(19) United States
(12) Patent Application Publication
(10) Pub. No.: US 2013/0248667 A1
(43) Pub. Date: Sep. 26, 2013

(54) Housing for Mounting an Electrical Device

(71) Applicant: Thomas & Betts International, Inc., Wilmington, DE (US)

(72) Inventors: Robert Fong, Bethlehem, PA (US); Daniel Gardner, Stewartsville, NJ (US)

(21) Appl. No.: 13/905,980

(22) Filed: May 30, 2013

Related U.S. Application Data
(62) Division of application No. 13/198,872, filed on Aug. 5, 2011.

(51) Int. Cl. H05K 5/00

(52) U.S. Cl. CPC H05K 5/00
USPC 248/218.4

(57) ABSTRACT

A rotatable lower housing for a high voltage electrical circuit or other high voltage electrical device is provided that allows a cylindrically-shaped lower housing to be rotatable with respect to a bracket for mounting the lower housing onto a support structure.

### CROSS-REFERENCE TO RELATED APPLICATION

This application is a divisional application of U.S. non-provisional patent application Ser. No. 13/198,872 and claims priority under 35 U.S.C. 121, based on U.S. non-provisional patent application Ser. No. 13/198,872 filed Aug. 5, 2011, the disclosure of which is hereby incorporated by reference herein.

### FIELD OF THE INVENTION

In general, the present invention relates to a rotatable lower housing for a high voltage electrical circuit or other high voltage electrical device. More particularly, the present invention relates to a cylindrically-shaped lower housing which is rotatable, a bracket for mounting the lower housing onto a support structure, and a surrounding element which allows the lower housing to be rotatable with respect to the bracket.

### BACKGROUND

In the utilities industry, often times high voltage electrical equipment or other high voltage electrical devices are mounted onto utility structures, such as transmission or distribution poles, prior to electrical cables, wires or connecting electrical equipment being connected to the high voltage electrical circuits or devices. When utility installers connect the electrical cables or wires to the electrical equipment, it is often desirable for the electrical equipment to be in proper alignment with the connecting electrical equipment, as such electrical circuits can be quite heavy and cumbersome to manipulate, often requiring the assistance of a lift truck or other heavy equipment.

### SUMMARY OF THE INVENTION

The present invention provides a rotatable lower housing for a high voltage electrical circuit or other high voltage electrical device which allows a utility installer to rotate the high voltage electrical device so that it is in proper alignment with the connecting electrical equipment. The invention comprises a lower housing which is rotatable. A bracket is provided for mounting the rotatable lower housing to a utility structure. The embodiment provided allows for the lower housing to be rotatable with respect to the bracket. For the embodiment presented, the term “rotatable” is considered to be any rotation of at least 5 degrees of the lower housing. The preferred embodiment comprises a one-piece surrounding mounting bracket that completely surrounds the lower housing, allowing the lower housing to be rotatable within the one-piece surrounding mounting bracket.

### BRIEF DESCRIPTION OF THE DRAWINGS

FIG. 1 is a plan view of a rotatable lower housing and a one-piece surrounding mounting bracket for a high voltage electrical device of the present invention taken along section 1-1 of FIG. 2.

FIG. 2 is cross-sectional elevation view of a rotatable lower housing and a one-piece surrounding mounting bracket for a high voltage electrical device of the present invention taken along section 2-2 of FIG. 1.

FIG. 3 is a front perspective view of a rotatable lower housing and a one-piece surrounding mounting bracket for a high voltage electrical device of the present invention.

FIG. 4 is a side elevation view of a high voltage electrical device installed in a rotatable lower housing and one-piece surrounding mounting bracket of the present invention with the rotatable lower housing and one-piece surrounding mounting bracket mounted onto a utility structure.

FIG. 5 is a front perspective view of a high voltage electrical device installed in a rotatable lower housing and one-piece surrounding mounting bracket of the present invention with the rotatable lower housing and one-piece surrounding mounting bracket mounted onto a utility structure.

### DETAILED DESCRIPTION OF THE PREFERRED EMBODIMENT(S)

The above and other features, aspects and advantages of the present invention will now be discussed in the following detailed description of preferred embodiments and appended claims, which are to be considered in conjunction with the accompanying drawings in which identical reference characters designate like elements throughout the views.

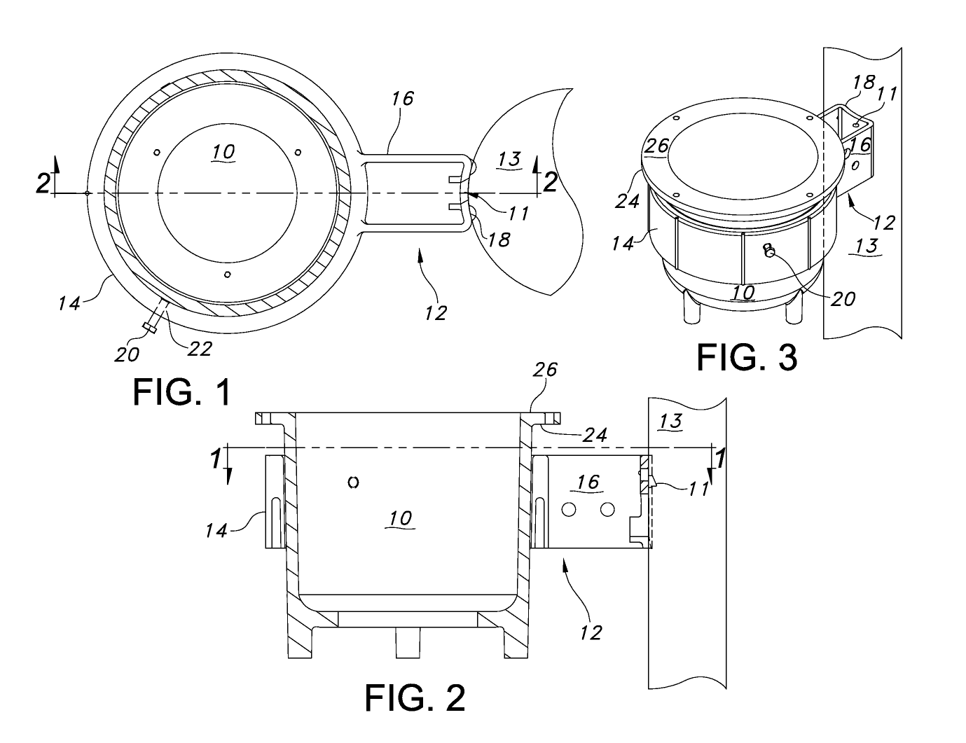

Shown in FIG. 1 is a plan view of a preferred embodiment of the present invention, which is a rotatable lower housing 10 for a single phase recloser of a high voltage electrical circuit or another high voltage electrical device. The lower housing may be made of a corrosion-resistant metal, such as stainless steel, or a high-strength plastic. The housing may also be painted with a UV and/or corrosion-resistant paint for further protection from the environment. FIG. 1 shows the cylindrical rotatable lower housing 10 being completely surrounded by a one-piece surrounding mounting bracket 12. The one-piece surrounding mounting bracket 12 comprises a ring 14 which completely surrounds the lower housing 10. At least two parallel side walls 16 are shown protruding from the ring 14, and a rear wail 18 is shown which connects the two side walls 16 and is perpendicular to the side walls 16. The rear wall 18 allows the one piece surrounding mounting bracket 12 to be mounted to a support structure 13, such as a utility or distribution pole, by hardware such as bolts or screws which are received by at least one aperture 11 in the rear wall 18 to attach the rear wall 18 to the support structure 13. For ease of installation and assembly of the one-piece surrounding mounting bracket 12, it may be a precast component which is made of as metallic or high-strength plastic material. It may also be formed of a weather resistant steel such as stainless steel or galvanized steel.

Also shown in FIG. 1 is an anti-rotation fastener 20. The anti-rotation fastener 20 is received through an aperture 22 that is contained within the ring 14. The anti-rotation fastener 20 may, for example, be a screw which can be loosened or tightened within the aperture 22 that is contained in the ring 14 such that when tightened, the screw contacts the rotatable lower housing 10, thereby preventing rotation of the housing 10. Likewise, the anti-rotation fastener 20 can be loosened such that it does not contact the lower housing 10, thereby allowing the lower housing 10 to freely rotate within the ring 14 of the one-piece surrounding mounting bracket 12. In FIG. 1, only one anti-rotation fastener 20 is shown, however, it is understood that more than one anti-rotation fastener may be used at multiple locations on the ring 14 of the surrounding mounting bracket 12.

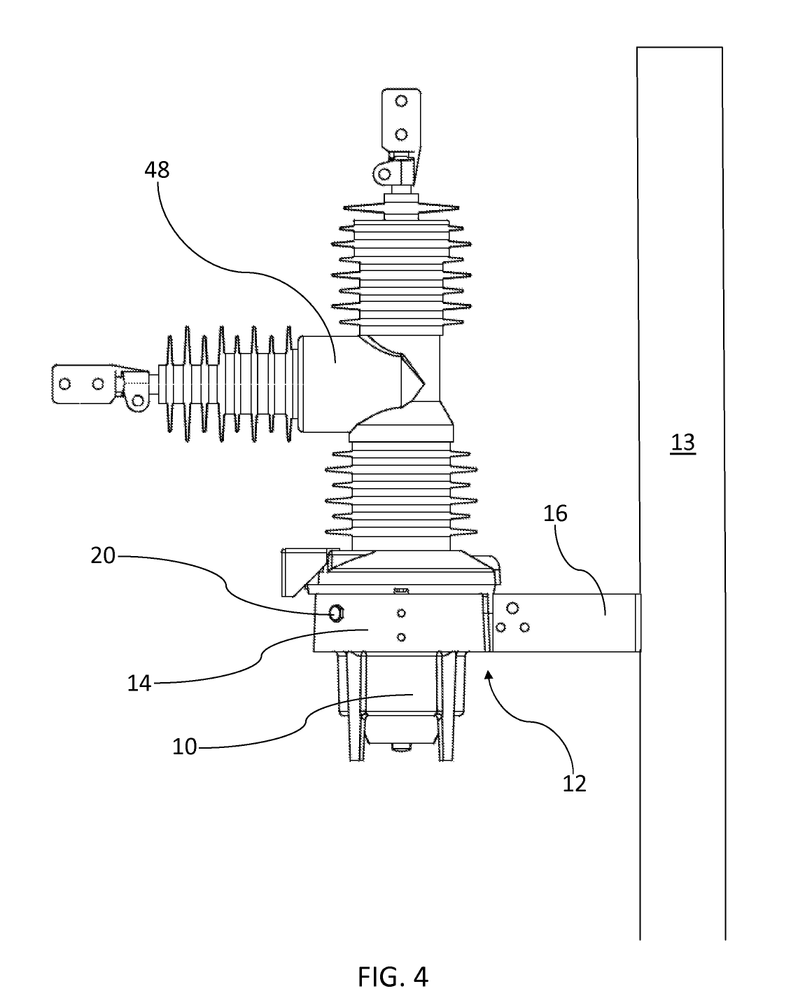

Shown in FIG. 2 is a cross-sectional elevation view of the preferred embodiment of the present invention. In FIG. 2, a radial flange 26 of the rotatable lower housing 10 is shown, and a lip 24 of the radial flange 26 is also shown. The lip 24 and the radial flange 26 are integrally formed with the rotatable lower housing 10. The presence of the lip 24 prevents downward vertical movement of the rotatable lower housing 10 through the one-piece surrounding mounting bracket 12 when the lip 24 is in contact with the one-piece surrounding mounting bracket 12. FIG. 3 shows a front perspective view of the preferred embodiment of the present invention and again shows each of the elements previously discussed in FIGS. 1 and 2.

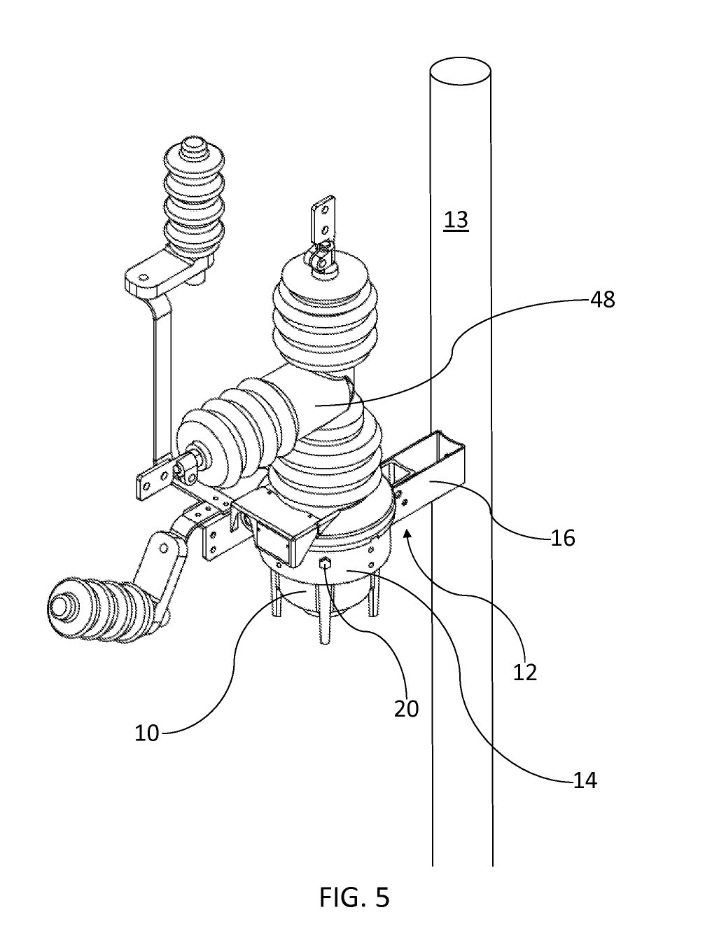

Shown in FIGS. 4 and 5 are a side elevation view and a front perspective view of a high voltage electrical device 48 installed in a rotatable lower housing 10 and one-piece surrounding mounting bracket 12 of the present invention with the rotatable lower housing 10 and one-piece surrounding mounting bracket 12 mounted onto a utility support structure 13. Both figures show how the high voltage electrical device 48 is seated within the rotatable lower housing 10. From these figures, it is easy to understand how the rotatable lower housing 10 can assist maintenance personnel which would perform work on the high voltage electrical device 48, because the rotatable lower housing 10 enables the high voltage electrical device 48 to be rotated to the desirable position for the maintenance personnel for easy installation of power lines and other equipment that attaches to the high voltage electrical device 48. This prevents the need for lift tracks or other heavy equipment to reposition the, usually cumbersome, high voltage electrical device 48.

Although the invention has been described in detail above, it is expressly understood that it will be apparent to persons skilled in the relevant art that the invention may be modified without departing from the spirit of the invention. Various changes of form, design, or arrangement may be made to the invention without departing from the spirit and scope of the invention. Therefore, the above mentioned description is to be considered exemplary, rather than limiting, and the true scope of the invention is that defined in the following claims.

What is claimed is:

1. A housing for mounting a high voltage electrical device onto a utility support structure comprising:
a lower housing which is rotatable and which houses a high voltage electrical device;
a mourning bracket that at least partially surrounds the lower housing for mounting the lower housing onto the utility support structure;
a fastener for selectively preventing the lower housing which houses the high voltage electrical device from rotating within the mounting bracket when the fastener is tightened or for allowing the lower housing which houses the high voltage electrical device to rotate within the mounting bracket when the fastener is loosened;
wherein the mounting bracket comprises a ring that at least partially surrounds the lower housing that houses the high voltage electrical device and at least two parallel side walls which protrude from the ring of the mounting bracket and a rear wail which is perpendicular to the side walls and which connects the side walls and fixedly abuts the utility support structure for mounting to the utility support structure; and
wherein the mounting bracket and ring Comprise a one-piece component.

2. The housing of claim 1 wherein an aperture is contained Within the mounting bracket for receiving the fastener.

3. The housing of claim 1 wherein the fastener is a screw which can be loosened such that the tower housing which houses the high voltage electrical device can be freely rotated to adjust the position of the lower housing or tightened such that the lower housing can be in a fixed position.

4. The housing of claim 1 wherein the lower housing which houses the high voltage electrical device has a lip surrounding a radial flange of the lower housing and wherein the ring of the mounting bracket can contact the lip to prevent downward vertical movement of the rotatable lower housing.

5. The housing of claim 1 wherein the mounting bracket which mounts the lower housing that houses the high voltage electrical device to the utility support structure is made of a metallic material or a high-strength plastic material.
